(19) United States
(12) Patent Application Publication
(10) Pub. No.: US 2026/0261232 A1
(43) Pub. Date: Sep. 3, 2026

(54) PHOTOVOLTAIC MODULE FRAME AND PHOTOVOLTAIC MODULE

(71) Applicant: LONGI GREEN ENERGY TECHNOLOGY CO., LTD., Xi'an (CN)

(72) Inventors: Liangliang XU, Xi'an (CN); Chunnuan FENG, Xi'an (CN); Zhengdong LIU, Xi'an (CN); Chuanxin XU, Xi'an (CN)

(21) Appl. No.: 18/993,688

(22) PCT Filed: May 31, 2023
(86) PCT No.: PCT/CN2023/097459

§ 371 Date: Jan. 13, 2025

(30) Foreign Application Priority Data
Aug. 19, 2022 (CN) 202222196972.5

(51) Int. Cl. H02S 30/10; H10F 19/90

(52) U.S. Cl. CPC H02S 30/10; H10F 19/904

(57) ABSTRACT

This application discloses a photovoltaic module and frame and a photovoltaic module. In one example, a photovoltaic module frame includes: a side plate, a bottom plate and a baffle plate that are fixed to a first side of the side plate. When the bottom plate is bonded to the bottom surface of the photovoltaic laminate, a surface of the baffle plate facing away from the bottom plate is lower than or flush with a light receiving surface of the photovoltaic laminate. The bottom plate, the side plate, and the baffle plate enclose a groove. A first protruding structure extending along a length direction of the side plate is arranged on the side plate. The groove is divided by the first protruding structure into a first overflow groove and a second overflow groove.

### CROSS-REFERENCE TO RELATED APPLICATIONS

The present disclosure claims priority to Chinese Patent Application No. 202222196972.5, filed with the China National Intellectual Property Administration on Aug. 19, 2022 and entitled “PHOTOVOLTAIC MODULE FRAME AND PHOTOVOLTAIC MODULE”, which is incorporated herein by reference in its entirety.

### TECHNICAL FIELD

This application relates to the field of photovoltaic technologies, and in particular, to a photovoltaic module frame and a photovoltaic module.

### BACKGROUND

A photovoltaic module is a most important part in a solar power generation system, and the photovoltaic module includes a photovoltaic laminate and a frame arranged around the photovoltaic laminate.

At present, the frame includes an accommodating groove configured to accommodate an edge of the photovoltaic laminate. The accommodating groove includes a surface A located on a light receiving surface of the photovoltaic laminate, and the surface A protrudes from the photovoltaic laminate, which is likely to cause dust accumulation on the frame. To reduce the dust accumulation on the frame, the surface A is generally removed, that is, the frame is configured as a frame without the surface A.

However, when the frame without the surface A is bonded to the photovoltaic laminate through silicone, the silicone can easily overflow to the photovoltaic module due to the absence of an overflow groove on the surface A.

### SUMMARY

This application provides a photovoltaic module frame and a photovoltaic module, and aims to resolve the problem that glues can easily overflow when a frame is bonded to a photovoltaic laminate.

According to a first aspect, an embodiment of this application provides a photovoltaic module frame, including: a side plate, and a bottom plate and a baffle plate that are fixed to a first side of the side plate, where the bottom plate is configured to be bonded to a bottom surface of a photovoltaic laminate, and the baffle plate is configured to be bonded to a side wall of the photovoltaic laminate;
when the bottom plate is bonded to the bottom surface of the photovoltaic laminate, a surface of the baffle plate facing away from the bottom plate is lower than or flush with a light receiving surface of the photovoltaic laminate; and
the bottom plate, the side plate, and the baffle plate enclose a groove, a first protruding structure extending along a length direction of the side plate is arranged on the side plate, and the groove is divided by the first protruding structure into a first overflow groove and a second overflow groove.

Optionally, along a direction from the side plate to the side wall of the photovoltaic laminate, a width of the first protruding structure is less than a width of the baffle plate; and/or,
along a direction from the baffle plate to the bottom plate, a ratio of a distance between the baffle plate and the first protruding structure to a distance between the bottom plate and the first protruding structure ranges from 0.9 to 1.1.

Optionally, a ratio of a width of the first protruding structure to a width of the baffle plate ranges from 0.4 to 0.7.

Optionally, a cross section of the first protruding structure is in a shape of a triangle.

Optionally, a plurality of limiting protrusions are arranged at intervals on the bottom plate, and each of the limiting protrusions extends along the length direction of the side plate.

Optionally, a protruding height of each of the limiting protrusions is greater than or equal to 0.3 millimeters and less than or equal to 0.7 millimeters.

Optionally, the photovoltaic module frame further includes a reinforcing plate arranged opposite to the side plate and a bearing plate fixed to the first side of the side plate, where one end of the reinforcing plate is connected to an end of the bottom plate facing away from the side plate, and another end of the reinforcing plate is connected to the bearing plate; and
a glue storage plate is arranged on a second side of the reinforcing plate, the second side of the reinforcing plate is a side of the reinforcing plate facing away from the side plate, a glue storage groove is provided on the glue storage plate, and the glue storage groove extends along the length direction of the side plate.

Optionally, a cross section of the glue storage groove is rectangular or arc-shaped.

Optionally, an end of the glue storage plate facing away from the reinforcing plate inclines toward the bearing plate to form an inclined portion, and the glue storage groove is connected to the inclined portion through a chamfer.

According to a second aspect, an embodiment of this application provides a photovoltaic module, including a photovoltaic laminate and at least one photovoltaic module frame according to the first aspect.

Optionally, the photovoltaic module frame is a frame arranged at a short side of the photovoltaic laminate.

In the embodiments of this application, the photovoltaic module frame includes the baffle plate fixed to the first side of the side plate, the baffle plate is configured to be bonded to the side wall of the photovoltaic laminate, the bottom plate, the side plate, and the baffle plate enclose a groove, the first protruding structure extending along the length direction of the side plate is arranged on the side plate, and the groove is divided by the first protruding structure into the first overflow groove and the second overflow groove. When the photovoltaic module frame is bonded to the photovoltaic laminate, extra silicone can be accommodated through the first overflow groove and the second overflow groove, thereby preventing the silicone from overflowing to a light receiving surface of the photovoltaic module, that is, preventing glue overflow on a front surface of the photovoltaic module. In addition, the silicone can be prevented from overflowing through the baffle plate, saving labor costs and time costs for cleaning overflowed silicone. In addition, through the first overflow groove and the second overflow groove among the bottom plate, the side plate, and the baffle plate, the silicone can fill up space between any one of the bottom plate, the side plate, or the baffle plate and the side wall of the photovoltaic laminate, so that bonding between the photovoltaic laminate and the photovoltaic module frame is firmer.

The foregoing description is only an overview of the technical solutions of this application. In order to understand the technical means of this application more clearly, implementation can be performed according to content of the specification. In addition, to make the foregoing and other objectives, features, and advantages of this application more comprehensible, specific implementations of this application are especially listed below.

### BRIEF DESCRIPTION OF THE DRAWINGS

To describe the technical solutions in the embodiments of the present disclosure or the related art more clearly, the following briefly describes accompanying drawings required for describing the embodiments or the related art. Apparently, the accompanying drawings in the following description show some embodiments of the present disclosure, and a person of ordinary skill in the art may still derive other accompanying drawings from these accompanying drawings without creative efforts.

FIG. 1 is a schematic diagram of a photovoltaic module frame according to an embodiment of this application;

FIG. 2 is a schematic diagram of assembly of a photovoltaic module frame and a photovoltaic laminate according to an embodiment of this application;

FIG. 3 is a schematic diagram of a photovoltaic module frame after glue injection according to an embodiment of this application;

FIG. 4 is a schematic diagram of a second frame according to an embodiment of this application;

FIG. 5 is a front view of a photovoltaic module according to an embodiment of this application;

FIG. 6 is a side view of a photovoltaic module according to an embodiment of this application;

FIG. 7 is a front view of a first cushion block according to an embodiment of this application;

FIG. 8 is a top view of a first cushion block according to an embodiment of this application;

FIG. 9 is a front view of a second cushion block according to an embodiment of this application;

FIG. 10 is a top view of a second cushion block according to an embodiment of this application;

FIG. 11 is a front view of a clamping member according to an embodiment of this application;

FIG. 12 is a side view of a clamping member according to an embodiment of this application;

FIG. 13 is a schematic diagram of mounting of a clamping member according to an embodiment of this application;

FIG. 14 is a front view of a protection plate according to an embodiment of this application;

FIG. 15 is a side view of a protection plate according to an embodiment of this application; and

FIG. 16 is a schematic diagram of mounting of a protection plate according to an embodiment of this application.

### LIST OF REFERENCE NUMERALS

10—First frame, 20—Second frame, 30—Photovoltaic laminate, 40—First cushion block, 50—Second cushion block, 60—Clamping member, 70—Protection plate, 11—Side plate, 12—Bottom plate, 13—Baffle plate, 14—Bearing plate, 15—Reinforcing plate, 16—Glue storage plate, 101—First overflow groove, 102—Second overflow groove, 111—First protruding structure, 121—Limiting protrusion, 161—Glue storage groove, 162—Inclined portion, 21—Side wall plate, 22—Mounting plate, 23—Top plate, 231—Third overflow groove, 61—Clamping protrusion, 62—First guide surface, and 63—Second guide surface.

### DETAILED DESCRIPTION

The following describes exemplary embodiments of this application in further detail with reference to the accompanying drawings. Although the exemplary embodiments of this application are shown in the accompanying drawings, it should be understood that, this application can be implemented in various manners and should not be limited by the embodiments described herein. On the contrary, the embodiments are provided, so that this application can be understood more thoroughly and a scope of this application can be completely conveyed to a person skilled in the art.

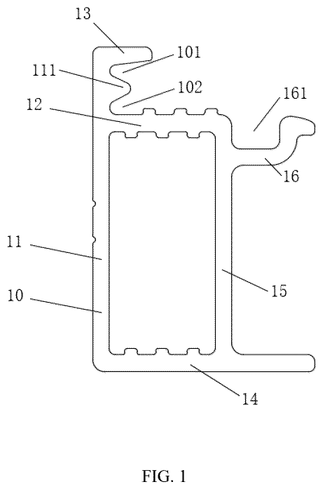

Referring to FIG. 1, an embodiment of this application discloses a photovoltaic module frame, including a side plate 11, and a bottom plate 12 and a baffle plate 13 that are fixed to a first side of the side plate 11, where the bottom plate 12 is configured to be bonded to a bottom surface of a photovoltaic laminate, and the baffle plate 13 is configured to be bonded to a side wall of the photovoltaic laminate; when the bottom plate 12 is bonded to the bottom surface of the photovoltaic laminate, a surface of the baffle plate 13 facing away from the bottom plate 12 is lower than or flush with a light receiving surface of the photovoltaic laminate; the bottom plate 12, the side plate 11, and the baffle plate 13 enclose a groove, where a groove opening of the groove faces the side wall of the photovoltaic laminate; and a first protruding structure 111 extending along a length direction of the side plate 11 is arranged on the side plate 11, and the groove is divided by the first protruding structure 111 into a first overflow groove 101 and a second overflow groove 102.

Specifically, the photovoltaic module frame may be made of aluminum alloy or steel and is configured to protect the photovoltaic laminate. The side plate 11, the bottom plate 12, and the baffle plate 13 included in the photovoltaic module frame may be integrally formed, or may be manufactured separately and then fixedly connected to each other in a soldering manner or the like.

A surface illuminated by light of the photovoltaic laminate is the light receiving surface, and a surface opposite to the light receiving surface of the photovoltaic laminate is the bottom surface. The bottom plate 12 may be bonded to the bottom surface of the photovoltaic laminate through silicone. An end of the baffle plate 13 facing away from the side plate 11 may be bonded to the side wall of the photovoltaic laminate through silicone. When the bottom plate 12 is bonded to the bottom surface of the photovoltaic laminate, the bottom plate 12 and the baffle plate 13 are fixed to the first side of the side plate 11 close to the photovoltaic laminate. When the bottom plate 12 is bonded to the bottom surface of the photovoltaic laminate, the surface of the baffle plate 13 facing away from the bottom plate 12 is flush with the light receiving surface of the photovoltaic laminate, that is, various positions on the surface of the baffle plate 13 facing away from the bottom plate 12 have consistent heights.

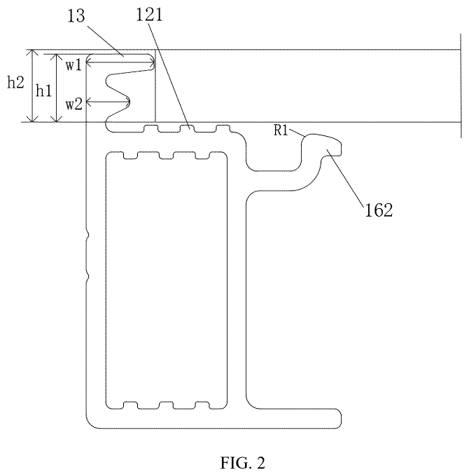

That the surface of the baffle plate 13 facing away from the bottom plate 12 is lower than or flush with the light receiving surface of the photovoltaic laminate is that, along a direction from the bottom plate 12 to the baffle plate 13, a distance between the surface of the baffle plate 13 facing away from the bottom plate 12 and the bottom surface of the photovoltaic laminate is less than or equal to a thickness of the photovoltaic laminate. Referring to FIG. 2, the distance between the surface of the baffle plate 13 facing away from the bottom plate 12 and the bottom surface of the photovoltaic laminate is a distance between the surface of the baffle plate 13 facing away from the bottom plate 12 and the bottom surface of the photovoltaic laminate along the direction from the bottom plate 12 to the baffle plate 13, as shown by “hl” in FIG. 2, and the thickness of the photovoltaic laminate is a dimension of the photovoltaic laminate along the direction from the bottom plate 12 to the baffle plate 13, as shown by “h2” in FIG. 2, where h1 is less than or equal to h2. A difference between the thickness of the photovoltaic laminate and the distance between the surface of the baffle plate 13 facing away from the bottom plate 12 and the bottom surface of the photovoltaic laminate may be set to be greater than or equal to 0.2 millimeters and less than or equal to 0.5 millimeters. For example, the difference between h2 and h1 may be set to 0.2 millimeters, 0.25 millimeters, 0.3 millimeters, 0.35 millimeters, 0.4 millimeters, or 0.5 millimeters.

When the bottom plate 12 is bonded to the bottom surface of the photovoltaic laminate, the surface of the baffle plate 13 facing away from the bottom plate 12 is lower than or flush with the light receiving surface of the photovoltaic laminate, rainwater can directly flow downward from the baffle plate 13 to remove dust, that is, the rainwater is not blocked by the frame in a process of scouring the dust, thereby improving a dust removing effect of the photovoltaic module frame. In addition, the surface of the baffle plate 13 facing away from the bottom plate 12 is not higher than the light receiving surface of the photovoltaic laminate, the light receiving surface of the photovoltaic laminate is not blocked by the photovoltaic module frame, thereby increasing a light receiving area of the photovoltaic laminate and further improving performance of the photovoltaic laminate.

The groove enclosed by the bottom plate 12, the side plate 11, and the baffle plate 13 extends along the length direction of the side plate 11, the first protruding structure 111 extends along the length direction of the side plate 11, and groove openings of both the first overflow groove 101 and the second overflow groove 102 face the side wall of the photovoltaic laminate. The first overflow groove 101 is enclosed by the baffle plate 13, the side plate 11, and the first protruding structure 111, and the second overflow groove 102 is enclosed by the first protruding structure 111, the side plate 11, and the bottom plate 12. A size of each overflow groove may be set as required, which is not limited in this embodiment.

The photovoltaic module frame is bonded to the photovoltaic laminate through silicone, and in a process that the photovoltaic laminate is bonded to the photovoltaic module frame, the silicone enters the second overflow groove 102 from the bottom plate 12 under the action of squeezing and enters the first overflow groove 101 from the second overflow groove 102, that is, the silicone can be accommodated by the first overflow groove 101 and the second overflow groove 102. Therefore, through the first overflow groove 101 and the second overflow groove 102, the silicone can be prevented from overflowing to the outside of the baffle plate 13, that is, the silicone is prevented from overflowing to a light receiving surface of the photovoltaic module and polluting the light receiving surface of the photovoltaic module and a production device. In addition, through the first overflow groove 101 and the second overflow groove 102, the silicone can be prevented from overflowing to the outside of the baffle plate 13 without setting a glue cleaning process, thereby saving labor costs and time costs for cleaning overflowed silicone, and improving production efficiency of the photovoltaic module. In addition, through the first overflow groove and the second overflow groove among the bottom plate 12, the side plate 11, and the baffle plate 13, the silicone can fill up space between any one of the bottom plate 12, the side plate 11, or the baffle plate 13 and the side wall of the photovoltaic laminate, so that bonding between the photovoltaic laminate and the photovoltaic module frame is firmer.

Optionally, along a direction from the side plate 11 to the side wall of the photovoltaic laminate, a width of the first protruding structure 111 is less than a width of the baffle plate 13, and/or along a direction from the baffle plate 13 to the bottom plate 12, a ratio of a distance between the baffle plate 13 and the first protruding structure 111 to a distance between the bottom plate 12 and the first protruding structure 111 ranges from 0.9 to 1.1.

Specifically, the width of the first protruding structure 111 is less than the width of the baffle plate 13, where the width of the first protruding structure 111 is a width between an end of the first protruding structure 111 away from the side plate 11 and a side wall of the side plate 11 facing away from a side wall of the bottom plate 12 along the direction from the side plate 11 to the side wall of the photovoltaic laminate, as shown by “w2” in FIG. 2; and the width of the baffle plate 13 is a width between a surface of the baffle plate 13 facing away from the side plate 11 and the side wall of the side plate 11 facing away from the side wall of the bottom plate 12 along the direction from the side plate 11 to the side wall of the photovoltaic laminate, as shown by “w1” in FIG. 2. By setting the width of the first protruding structure 111 to be less than the width of the baffle plate 13, it is ensured that the baffle plate 13 is bonded to the side wall of the photovoltaic laminate, and it is also ensured that the silicone in the second overflow groove 102 can flow into the first overflow groove 101.

Along the direction from the side plate 11 to the side wall of the photovoltaic laminate, a ratio of the width of the first protruding structure 111 to the width of the baffle plate 13 ranges from 0.4 to 0.7, where the ratio of the width w2 of the first protruding structure 111 to the width w1 of the baffle plate 13 may be 0.4, 0.45, 0.5, 0.55, 0.6, or 0.7. By setting a range of the ratio of the width of the first protruding structure 111 to the width of the baffle plate 13, it is ensured that sufficient space is provided for the silicone to overflow from the second overflow groove 102 to toward the first overflow groove 101 in a process that the photovoltaic laminate and the photovoltaic module frame are bonded through silicone.

The distance between the baffle plate 13 and the first protruding structure 111 is a distance between a surface of the first protruding structure 111 close to the baffle plate 13 and a surface of the baffle plate 13 close to the bottom plate 12 along the direction from the baffle plate 13 to the bottom plate 12. The distance between the bottom plate 12 and the first protruding structure 111 is a distance between a surface of the first protruding structure 111 close to the bottom plate 12 and a surface of the bottom plate 12 close to the baffle plate 13 along the direction from the baffle plate 13 to the bottom plate 12. The ratio of the distance between the baffle plate 13 and the first protruding structure 111 to the distance between the bottom plate 12 and the first protruding structure 111 ranges from 0.9 to 1.1. For example, the ratio of the distance between the baffle plate 13 and the first protruding structure 111 to the distance between the bottom plate 12 and the first protruding structure 111 may be 0.9, 0.92, 0.95, 1, 1.05, or 1.1. In this ratio range, a difference between the distance between the baffle plate 13 and the first protruding structure 111 and the distance between the bottom plate 12 and the first protruding structure 111 can be relatively small, so that glue overflowed in the first overflow groove 101 and the second overflow groove 102 is more uniform.

A shape of a cross section of the first protruding structure 111 may be set according to an actual requirement, for example, may be set to a rectangle, a triangle, or a trapezoid. When the shape of the cross section of the first protruding structure 111 is a triangle, the surface of the first protruding structure 111 close to the baffle plate 13 is an inclined surface, and the surface of the first protruding structure 111 close to the bottom plate 12 is an inclined surface, so that the distance between the baffle plate 13 and the first protruding structure 111 may be a smallest distance between the surface of the first protruding structure 111 close to the baffle plate 13 and the surface of the baffle plate 13 close to the bottom plate 12 along the direction from the baffle plate 13 to the bottom plate 12; and the distance between the bottom plate 12 and the first protruding structure 111 may be a smallest distance between the surface of the first protruding structure 111 close to the bottom plate 12 and the surface of the bottom plate 12 close to the baffle plate 13 along the direction from the baffle plate 13 to the bottom plate 12.

Optionally, the cross section of the first protruding structure 111 is in a shape of a triangle.

Specifically, a section in the photovoltaic module frame perpendicular to the length direction of the side plate 11 is a cross section, and a cross section of a structure formed by the first overflow groove 101, the first protruding structure 111, and the second overflow groove 102 is wave-shaped. A corner in the triangular cross-sectional shape of the first protruding structure 111 facing away from the side plate 11 may be set to a rounded corner. That is, the surface of the first protruding structure 111 close to the baffle plate 13 and the surface of the first protruding structure 111 close to the bottom plate 12 are smoothly connected through a first rounded corner.

By setting the shape of the cross section of the first protruding structure 111 to a triangle, that is, the surface of the first protruding structure 111 close to the baffle plate 13 is an inclined surface, and the surface of the first protruding structure 111 close to the bottom plate 12 is an inclined surface, the silicone can be better guided to overflow from the second overflow groove 102 toward the first overflow groove 101 when the photovoltaic module frame and the photovoltaic laminate are bonded through silicone.

The surface of the baffle plate 13 close to the bottom plate 12 is an inclined surface, the inclined surface inclines toward the light receiving surface of the photovoltaic laminate, and an angle between the surface of the baffle plate 13 close to the bottom plate 12 and the surface of the baffle plate 13 facing away from the bottom plate 12 ranges from 3 degrees to 6 degrees. For example, the angle between the surface of the baffle plate 13 close to the bottom plate 12 and the surface of the baffle plate 13 facing away from the bottom plate 12 may be 3 degrees, 3.5 degrees, 4 degrees, 5 degrees, 5.5 degrees, or 6 degrees. By setting the surface of the baffle plate 13 close to the bottom plate 12 to an inclined surface, the first overflow groove 101 can accommodate more silicone while the smallest distance between the surface of the first protruding structure 111 close to the baffle plate 13 and the surface of the baffle plate 13 close to the bottom plate 12 remains unchanged. A bottom portion of the first overflow groove 101 is arc-shaped, the bottom portion of the first overflow groove 101 faces an opening direction of the first overflow groove 101, and the bottom portion of the first overflow groove 101 and the surface of the baffle plate 13 close to the bottom plate 12 are smoothly connected to the surface of the first protruding structure 111 close to the baffle plate 13. A bottom portion of the second overflow groove 102 is arc-shaped, the bottom portion of the second overflow groove 102 faces an opening direction of the second overflow groove 102, and the bottom portion of the second overflow groove 102 and the surface of the first protruding structure 111 close to the bottom plate 12 are smoothly connected to the surface of the bottom plate 12 close to the baffle plate 13.

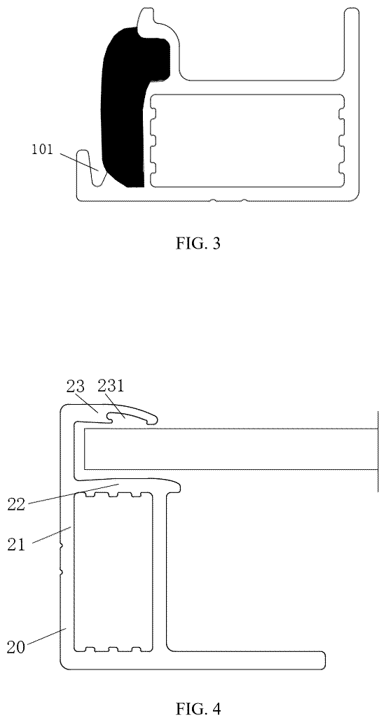

Referring to FIG. 3, when the photovoltaic module frame is bonded to the photovoltaic laminate through silicone, glue injection needs to be first performed on the photovoltaic module frame, and the photovoltaic module frame on which glue injection is performed is shown in FIG. 3. In this case, the side plate 11 of the photovoltaic module frame is placed downward, the groove openings of the first overflow groove 101 and the second overflow groove 102 face upward, and the silicone is distributed on the bottom plate 12 and the second overflow groove 102 under the action of gravity. When the photovoltaic laminate and the photovoltaic module frame on which glue injection is performed are assembled, under the action of squeezing, the silicone overflows from the second overflow groove 102 toward the first overflow groove 101 along a wave-shaped contour of the structured formed by the first overflow groove 101, the first protruding structure 111, and the second overflow groove 102, and through the arrangement of the wave-shaped contour, a flow direction of the silicone can be better guided. That is, the cross section of the structure formed by the first overflow groove 101, the first protruding structure 111, and the second overflow groove 102 is wave-shaped, so that the flow direction of the silicone can be better guided and the silicone can be accommodated, thereby preventing the silicone from overflowing to the light receiving surface of the photovoltaic laminate. In addition, it is ensured that the silicone fills up space between the first overflow groove 101 as well as the second overflow groove 102 and the side wall of the photovoltaic laminate after the photovoltaic laminate is bonded to the photovoltaic module frame, that is, a bonding effect of the side wall of the photovoltaic laminate is ensured.

Optionally, a plurality of limiting protrusions 121 are arranged at intervals on the bottom plate 12, and each of the limiting protrusions 121 extends along the length direction of the side plate 11; and a protruding height of each of the limiting protrusions 121 is greater than or equal to 0.3 millimeters and less than or equal to 0.7 millimeters.

Specifically, a quantity of the limiting protrusions 121 ranges from 2 to 5, and for example, the quantity of the limiting protrusions 121 may be set to 2, 3, 4, or 5. Referring to FIG. 1, three limiting protrusions 121 are arranged at intervals on the bottom plate 12, and protruding heights of the three limiting protrusions 121 are the same. The protruding height of the limiting protrusion 121 is a height between a surface of the limiting protrusion 121 facing away from the bottom plate 12 and the surface of the bottom plate 12 close to the baffle plate 13 along the direction from the bottom plate 12 to the baffle plate 13. Through the arrangement of the limiting protrusions 121, it can be ensured that the surface of the baffle plate 13 facing away from the bottom plate 12 is lower than or flush with the light receiving surface of the photovoltaic laminate when the bottom plate 12 is bonded to the bottom surface of the photovoltaic laminate. In addition, the silicone can be accommodated through a groove formed between every two adjacent limiting protrusions 121, and after the silicone is cured, the limiting protrusions 121 can limit the cured silicone to some extent, thereby preventing occurrence of relative sliding between the photovoltaic laminate and the photovoltaic module frame.

The protruding height of the limiting protrusion 121 may be set to be greater than or equal to 0.3 millimeters and less than or equal to 0.7 millimeters. For example, the protruding height of the limiting protrusion 121 may be set to 0.3 millimeters, 0.4 millimeters, 0.45 millimeters, 0.5 millimeters, 0.6 millimeters, or 0.7 millimeters. When the protruding height of the limiting protrusion 121 falls within this range, when the bottom plate 12 is bonded to the bottom surface of the photovoltaic laminate, a difference between a thickness of the photovoltaic laminate and a distance between the surface of the baffle plate 13 facing away from the bottom plate 12 and the bottom surface of the photovoltaic laminate falls within a suitable range.

Optionally, the photovoltaic module frame further includes a reinforcing plate 15 arranged opposite to the side plate 11 and a bearing plate 14 fixed to the first side of the side plate 11, where one end of the reinforcing plate 15 is connected to an end of the bottom plate 12 facing away from the side plate 11, and another end of the reinforcing plate 15 is connected to the bearing plate 14; and a glue storage plate 16 is arranged on a second side of the reinforcing plate 15, the second side of the reinforcing plate 15 is a side of the reinforcing plate 15 facing away from the side plate 11, a glue storage groove 161 is provided on the glue storage plate 16, and the glue storage groove 161 extends along the length direction of the side plate 11.

Specifically, the side plate 11, the bottom plate 12, the reinforcing plate 15, and the bearing plate 14 enclose a frame-shaped cavity. A plurality of reinforcing protrusions are arranged on both a surface of the bottom plate 12 facing away from the baffle plate 13 and a surface of the bearing plate 14 close to the bottom plate 12, and each of the reinforcing protrusions extends along the length direction of the side plate 11. Through the arrangement of the reinforcing plate 15 and the reinforcing protrusions, a structural strength of the photovoltaic module frame is enhanced, and the arrangement of the frame-shaped cavity reduces the weight of the photovoltaic module frame.

An opening of the glue storage groove 161 faces the bottom surface of the photovoltaic laminate. Along the direction from the bottom plate 12 to the baffle plate 13, a depth of the glue storage groove 161 may be set to 2 millimeters, 2.2 millimeters, 2.5 millimeters, 3 millimeters, 3.5 millimeters, or 4 millimeters. The glue storage groove 161 is configured to store the silicone used for bonding the photovoltaic module frame to the photovoltaic laminate. The glue storage groove 161 has a silicone storage function, and through the silicone stored in the glue storage groove 161, an amount of silicone used for bonding when the photovoltaic module frame is bonded to the photovoltaic laminate is ensured, thereby improving a bonding strength between the photovoltaic module frame and the photovoltaic laminate.

Optionally, a cross section of the glue storage groove 161 is rectangular or arc-shaped.

Specifically, when the cross section of the glue storage groove 161 is rectangular, the glue storage groove 161 is a rectangular groove; and when the cross section of the glue storage groove 161 is arc-shaped, the glue storage groove 161 is an arc-shaped groove. Referring to FIG. 1, the glue storage groove 161 in FIG. 1 is a rectangular groove. The glue storage groove 161 has a simple structure and is easy to process, and an opening of the rectangular groove or the arc-shaped groove facilitates injection of the silicone.

The glue storage plate 16 includes a glue storage bottom plate and a glue storage side plate, where the glue storage bottom plate is fixed to the second side of the reinforcing plate 15, and the glue storage side plate is fixed to an end of the glue storage bottom plate facing away from the reinforcing plate 15. The reinforcing plate 15, the glue storage bottom plate, and the glue storage side plate enclose a rectangular, and the rectangular groove is the glue storage groove 161.

Optionally, an end of the glue storage plate 16 facing away from the reinforcing plate 15 inclines toward the bearing plate 14 to form an inclined portion 162, and the glue storage groove 161 is connected to the inclined portion 162 through a chamfer.

Specifically, the glue storage groove 161 is in transition to the inclined portion 162 through a smooth chamfer, and the smooth chamfer is a second rounded corner, as shown by “R1” in FIG. 2, where a radius of the second rounded corner R1 may be set to be greater than or equal to 0.5 millimeters and less than or equal to 1 millimeter. For example, the radius of the second rounded corner may be set to 0.5 millimeters, 0.6 millimeters, 0.7 millimeters, 0.8 millimeters, 0.9 millimeters, or 1 millimeter.

A surface of the inclined portion 162 facing the photovoltaic laminate may be an arc surface. When the bottom plate 12 is bonded to the bottom surface of the photovoltaic laminate, the inclined portion 162 is bonded to the bottom surface of the photovoltaic laminate through silicone. Through the design of the second rounded corner and the arc surface of the inclined portion 162, when the photovoltaic laminate bears a front mechanical load and is deformed, contact stress of an edge of the photovoltaic module frame to the photovoltaic laminate can be reduced, thereby improving a front load strength that the photovoltaic laminate can bear.

Based on the above, an embodiment of this application discloses a photovoltaic module frame, the photovoltaic module frame includes the baffle plate fixed to the first side of the side plate, the baffle plate is configured to be bonded to the side wall of the photovoltaic laminate, the bottom plate, the side plate, and the baffle plate enclose a groove, the first protruding structure extending along the length direction of the side plate is arranged on the side plate, and the groove is divided by the first protruding structure into the first overflow groove and the second overflow groove. When the photovoltaic module frame is bonded to the photovoltaic laminate, extra silicone can be accommodated through the first overflow groove and the second overflow groove, thereby preventing the silicone from overflowing to a light receiving surface of the photovoltaic module, that is, preventing glue overflow on a front surface of the photovoltaic module. In addition, the silicone can be prevented from overflowing through the baffle plate, saving labor costs and time costs for cleaning overflowed silicone. In addition, through the first overflow groove and the second overflow groove among the bottom plate, the side plate, and the baffle plate, the silicone can fill up space between any one of the bottom plate, the side plate, or the baffle plate and the side wall of the photovoltaic laminate, so that bonding between the photovoltaic laminate and the photovoltaic module frame is firmer.

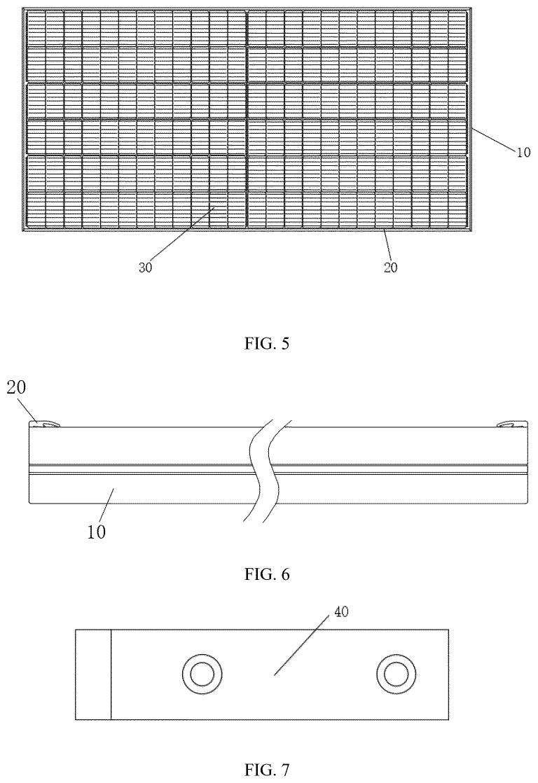

Referring to FIG. 5 and FIG. 6, an embodiment of this application further discloses a photovoltaic module, including a photovoltaic laminate 30 and at least one photovoltaic module frame described above, where the photovoltaic module frame is mounted at an edge of the photovoltaic laminate 30.

Specifically, the photovoltaic laminate 30 is also referred to as a solar power laminate, and the photovoltaic laminate 30 may include a glass cover, an upper encapsulating film, a cell string, a lower encapsulating film, and a back sheet. The photovoltaic laminate 30 is generally in a shape of a rectangle or a regular rectangle.

The photovoltaic module frame is a first frame 10, and the photovoltaic module may include one, two, three, or four first frames 10. When the photovoltaic module includes two first frames 10, the two first frames 10 may be arranged opposite to each other on two sides of the photovoltaic laminate 30.

The photovoltaic module may further include a second frame 20, where a structure of the second frame 20 is different from a structure of the first frame 10, and the first frame 10 and the second frame 20 may be together enclosed on a circumferential edge of the photovoltaic laminate 30. Referring to FIG. 4, the second frame 20 includes a side wall plate 21, and a mounting plate 22 and a top plate 23 that are fixed to a first side of the side wall plate 21, where the top plate 23, the side wall plate 21, and the mounting plate 22 enclose an accommodating groove configured to accommodate the edge of the photovoltaic laminate.

The accommodating groove extends along a length direction of the side wall plate 21. In a process of fixing a side of the photovoltaic laminate into the accommodating groove of the second frame 20, one layer of silicone may be dispensed in the accommodating groove in advance, so that the photovoltaic laminate can be bonded to the accommodating groove. The silicone can bond the side of the photovoltaic laminate to the accommodating groove, thereby improving connection reliability between the photovoltaic laminate and the second frame 20.

A third overflow groove 231 is provided on the top plate 23, the third overflow groove 231 is in communication with the accommodating groove, and an extending direction of the third overflow groove 231 is the same as an extending direction of the accommodating groove. In a process that the photovoltaic laminate enters the accommodating groove, the silicone is squeezed, and the silicone can enter the third overflow groove 231 and be discharged along the extending direction of the third overflow groove 231, thereby preventing the silicone from overflowing to the light receiving surface of the photovoltaic laminate. Through the arrangement of the third overflow groove 231, the silicone is prevented from overflowing to the light receiving surface of the photovoltaic laminate without adding a glue cleaning process, thereby saving labor costs and time costs for cleaning overflowed silicone.

Optionally, the photovoltaic module frame is a frame arranged at a short side of the photovoltaic laminate 30.

Specifically, the photovoltaic module frame, that is, the first frame 10 is arranged at the short side of the photovoltaic laminate 30, and the second frame 20 is arranged at a long side of the photovoltaic laminate 30, so that a length of the second frame 20 is greater than a length of the first frame 10. When the photovoltaic module includes two first frame 10 and two second frames 20, the two first frames 10 are respectively arranged on two sides along a length direction of the photovoltaic laminate 30, and the two second frames 20 are respectively arranged on two sides along a width direction of the photovoltaic laminate 30.

Connection stability between the second frame 20 and the photovoltaic laminate is better than connection stability between the first frame 10 and the photovoltaic laminate. In this embodiment of this application, by setting a shorter frame in the photovoltaic module as the first frame 10 and setting a longer frame in the photovoltaic module as the second frame 20, a dust removing effect and a glue overflow prevention effect of the photovoltaic module are improved while the connection reliability between the frames and the photovoltaic laminate is ensured. In addition, due to the arrangement of the second frame 20, the connection reliability between the frames and the photovoltaic laminate in the photovoltaic module is relatively good, and there is no need to replace common silicone with a structural adhesive, thereby saving costs. In addition, the second frame 20 may be manufactured and assembled with the photovoltaic laminate according to a routine process procedure, and there is no need to greatly modify the process procedure and a frame mounting device, thereby improving manufacturability of the photovoltaic module. In addition, the photovoltaic module includes at least one photovoltaic module frame described above, so that the photovoltaic module has the beneficial effects of the photovoltaic module frame, and details are not described herein.

Referring to FIG. 7 to FIG. 10, an embodiment of this application further relates to a cushion block configured for mounting of a photovoltaic module frame, where the cushion block includes two first cushion blocks 40 and two second cushion blocks 50, and the first cushion blocks 40 and the second cushion blocks 50 are all configured for mounting of the photovoltaic module frame to a photovoltaic laminate. Two first connection holes are provided on the first cushion block 40, and the two first connection holes are configured to be connected to a frame mounting device through connectors. Two second connection holes are provided on the second cushion block 50, and the two second connection holes are configured to be connected to the frame mounting device through connectors. The frame mounting device is configured to assemble the photovoltaic laminate and the photovoltaic module frame.

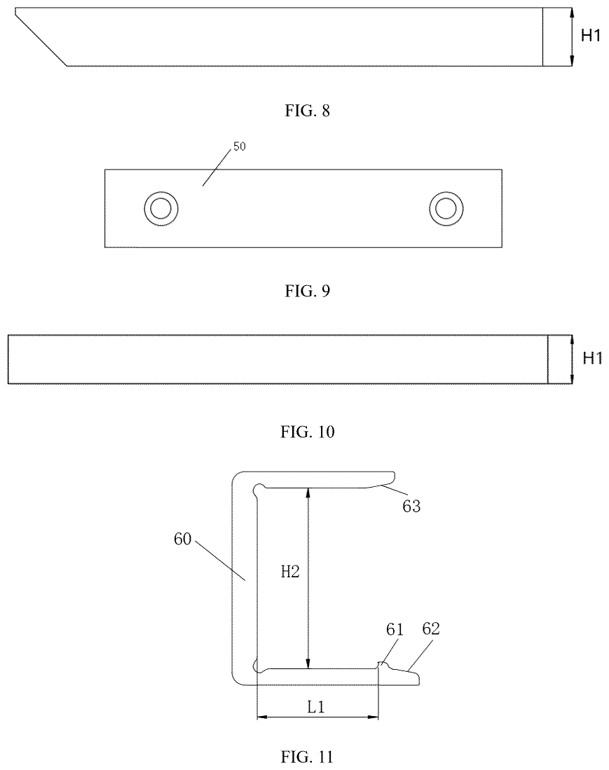

The first connection holes and the second connection holes are all stepped through holes. A height of the first cushion block 40 and a height of the second cushion block 50 are the same, as shown by “H1” in FIG. 8 and FIG. 10, where H1 may be set to 16 millimeters. The frame mounting device is further connected to a supporting block configured for mounting of the second frame 20. A height of the supporting block is different from the height of the cushion block, and a height difference between the supporting block and the cushion block may be determined according to a height difference between the side wall plate 21 of the second frame 20 and the side plate 11 of the photovoltaic module frame.

In this embodiment of this application, the second frame 20 may be mounted on the photovoltaic laminate by using a routine process procedure and the supporting block, and because the photovoltaic module frame still has the baffle plate 13, through the arrangement of the first cushion blocks 40 and the second cushion blocks 50 configured for mounting of the photovoltaic module frame to the photovoltaic laminate, the photovoltaic module frame may still be mounted on the photovoltaic laminate by using a routine process procedure with little modification on the frame mounting device. Therefore, the frame mounting device does not need to be greatly modified, thereby improving manufacturability of the photovoltaic module.

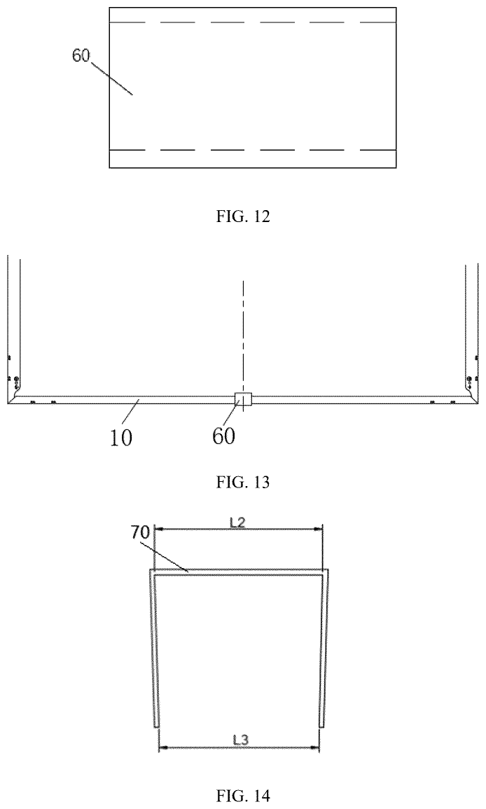

Referring to FIG. 11 to FIG. 13, an embodiment of this application further relates to a clamping member configured for a photovoltaic module. After frame mounting of the photovoltaic module is completed, processes such as curing, testing, and packaging further need to be performed. After frame mounting of the photovoltaic module is completed, a clamping member 60 needs to be used before the curing process is completed, and the clamping member 60 is removed for reuse after the curing process is completed and before the testing process is performed.

There are two clamping members 60, and each of the clamping members 60 is configured to clamp the photovoltaic module frame and the photovoltaic laminate. The clamping member 60 is of a U-shaped structure as a whole, and the clamping member 60 is made of a plastic material such as ABS (copolymer of Acrylonitrile (A), Butadiene (B) and Styrene (C)), PA6 (Polyamide/Nylon 6), or PC (polycarbonate). The clamping member 60 includes a clamping member side plate, a first clamping plate, and a second clamping plate, where the first clamping plate and the second clamping plate are fixed to the same side of the clamping member side plate, and the clamping member side plate, the first clamping plate, and the second clamping plate enclose a rectangular open groove. A surface of the first clamping plate close to the second clamping plate is formed by a first limiting surface and a second guide surface 63, where the second guide surface 63 is located on an end of the first clamping member facing away from the clamping member side plate. A surface of the second clamping plate close to the first clamping plate is formed by a second limiting surface and a first guide surface 62, where the first guide surface 62 is located on an end of the second clamping plate facing away from the clamping member side plate. A clamping protrusion 61 is arranged on the second clamping plate, and the first guide surface 62 is located on a side of the clamping protrusion 61 facing away from the clamping member side plate. Both the first guide surface 62 and the second guide surface 63 are inclined surfaces to meet a requirement of guiding mounting.

A difference between a distance between the first limiting surface of the first clamping plate and the second limiting surface of the second clamping plate as shown by “H2” in FIG. 11 and a height of the photovoltaic module frame as shown by “h1” in FIG. 2 is greater than or equal to 0 and less than or equal to 1 millimeter. A difference between a distance between a side wall of the clamping member side plate close to the second clamping plate and the clamping protrusion 61 as shown by “L1” in FIG. 11 and a width of the bearing plate 14 is greater than or equal to 0 and less than or equal to 1 millimeter. Referring to FIG. 13, during use of the clamping member 60, the clamping member is clamped in the middle of the photovoltaic module frame.

Through the arrangement of the clamping member 60, it can be ensured that the photovoltaic module frame is prevented from being separated from the photovoltaic laminate due to the weight of the photovoltaic module frame when the photovoltaic module is placed after frame mounting, thereby ensuring bonding firmness between the photovoltaic module frame and the photovoltaic laminate, and improving curing quality of the photovoltaic module.

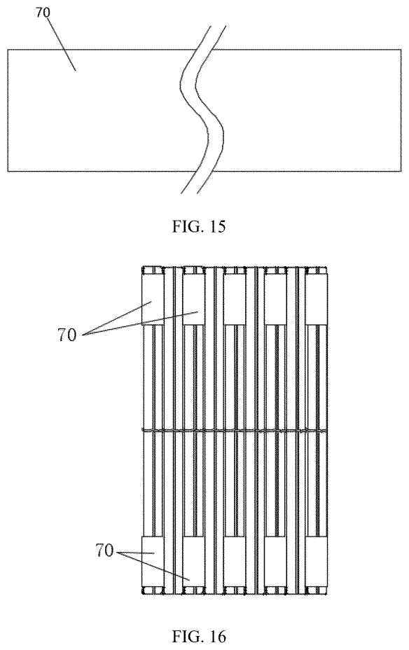

Referring to FIG. 14 to FIG. 16, an embodiment of this application further relates to a protection plate configured for packaging a photovoltaic module. The protection plate 70 is configured to package the photovoltaic module frame in the photovoltaic module, that is, the first frame 10, and the protection plate 70 is made of bobbin fibre paper with a thickness ranging from 3.5 millimeters to 4 millimeters. The protection plate 70 is of a U-shaped structure as a whole, and the protection plate 70 includes a packaging groove. A width of a bottom portion of the packaging groove as shown by “L2” in FIG. 14 is greater than a width of an opening of the packaging groove as shown by “L3” in FIG. 14, and a difference between the width of the bottom portion of the packaging groove as shown by “L2” in FIG. 14 and the height of the photovoltaic module frame as shown by “h1” in FIG. 2 is greater than or equal to 0 and less than or equal to 1 millimeter. Through the setting that the width of the bottom portion of the packaging groove is greater than the width of the opening of the packaging groove, it can be ensured that the protection plate 70 can be hardly separated from the photovoltaic module after being mounted. Four protection plates 70 need to be mounted correspondingly for one photovoltaic module, and two protection plates 70 are mounted correspondingly for each photovoltaic module frame. Therefore, for a plurality of photovoltaic modules, the plurality of photovoltaic modules are packaged by the protection plate 70 at an interval of one photovoltaic module, as shown in FIG. 16. Through the arrangement of the protection plate 70, quality problems such as a package seam or frame deformation caused by a height difference between the photovoltaic module frame and the second frame 20 can be avoided, thereby improving packaging quality.

It should be noted that, the terms “include”, “comprise”, and any variants thereof in this specification are intended to cover non-exclusive inclusion. Therefore, in the context of a process, a method, an object, or a device that includes a series of elements, the process, the method, the object, or the device not only includes such elements, but also includes other elements not specified expressly, or may include inherent elements of the process, the method, the object, or the device. Without more limitations, an element defined by the sentence “including one” does not exclude existence of other same elements in the process, the method, the object, or the device that includes the element.

The embodiments of this application are described above with reference to the accompanying drawings, but this application is not limited to the foregoing specific implementations, and the foregoing specific implementations are merely exemplary rather than limitative. A person of ordinary skill in the art can further make many forms under the teaching of this application without departing from the essence of this application and the protection scope of the claims, and all the forms fall within the protection scope of this application.

1. A photovoltaic module frame, comprising: a side plate, a bottom plate, and a baffle plate that are fixed to a first side of the side plate, the bottom plate is configured to be bonded to a bottom surface of a photovoltaic laminate, and the baffle plate is configured to be bonded to a side wall of the photovoltaic laminate; wherein
when the bottom plate is bonded to the bottom surface of the photovoltaic laminate, a surface of the baffle plate facing away from the bottom plate is lower than or flush with a light receiving surface of the photovoltaic laminate; and wherein
the bottom plate, the side plate, and the baffle plate enclose a groove, a first protruding structure extending along a length direction of the side plate is arranged on the side plate, and the groove is divided by the first protruding structure into a first glue overflow prevention groove and a second glue overflow prevention groove.

2. The photovoltaic module frame according to claim 1, wherein a width of the first protruding structure is less than a width of the baffle plate, wherein the width is measured along a direction from the side plate to the side wall of the photovoltaic laminate; and,
a ratio of a distance between the baffle plate and the first protruding structure to a distance between the bottom plate and the first protruding structure ranges from 0.9 to 1.1, wherein the distance is measured along a direction from the baffle plate to the bottom plate.

3. The photovoltaic module frame according to claim 1, wherein a ratio of a width of the first protruding structure to a width of the baffle plate ranges from 0.4 to 0.7, wherein the width is measured along a direction from the side plate to the side wall of the photovoltaic laminate.

4. The photovoltaic module frame according to claim 1, wherein a cross section of the first protruding structure is in a shape of a triangle.

5. The photovoltaic module frame according to claim 1, wherein a plurality of limiting protrusions are arranged at intervals on the bottom plate, and each of the limiting protrusions extends along the length direction of the side plate.

6. The photovoltaic module frame according to claim 5, wherein a protruding height of each of the limiting protrusions is greater than or equal to 0.3 millimeters and less than or equal to 0.7 millimeters.

7. The photovoltaic module frame according to any one of claim 1, further comprising a reinforcing plate arranged opposite to the side plate and a bearing plate fixed to the first side of the side plate, wherein one end of the reinforcing plate is connected to an end of the bottom plate facing away from the side plate, and the other end of the reinforcing plate is connected to the bearing plate; and
a glue storage plate is arranged on a second side of the reinforcing plate, the second side of the reinforcing plate is a side of the reinforcing plate facing away from the side plate, a glue storage groove is provided on the glue storage plate, and the glue storage groove extends along the length direction of the side plate.

8. The photovoltaic module frame according to claim 7, wherein a cross section of the glue storage groove is rectangular or arc-shaped.

9. The photovoltaic module frame according to claim 7, wherein an end of the glue storage plate facing away from the reinforcing plate inclines toward the bearing plate to form an inclined portion, and the glue storage groove is connected to the inclined portion through a chamfer.

10. A photovoltaic module, comprising a photovoltaic laminate and at least one photovoltaic module frame, wherein a photovoltaic module frame comprises:
a side plate, a bottom plate, and a baffle plate that are fixed to a first side of the side plate, the bottom plate is configured to be bonded to a bottom surface of a photovoltaic laminate, and the baffle plate is configured to be bonded to a side wall of the photovoltaic laminate; wherein
when the bottom plate is bonded to the bottom surface of the photovoltaic laminate, a surface of the baffle plate facing away from the bottom plate is lower than or flush with a light receiving surface of the photovoltaic laminate; and wherein
the bottom plate, the side plate, and the baffle plate enclose a groove, a first protruding structure extending along a length direction of the side plate is arranged on the side plate, and the groove is divided by the first protruding structure into a first glue overflow prevention groove and a second glue overflow prevention groove.

11. The photovoltaic module according to claim 10, wherein the photovoltaic module frame is a frame arranged at a short side of the photovoltaic laminate.

12. The photovoltaic module according to claim 10, wherein a width of the first protruding structure is less than a width of the baffle plate, wherein the width is measured along a direction from the side plate to the side wall of the photovoltaic laminate; and
wherein a ratio of a distance between the baffle plate and the first protruding structure to a distance between the bottom plate and the first protruding structure ranges from 0.9 to 1.1, wherein the distance is measured along a direction from the baffle plate to the bottom plate.

13. The photovoltaic module according to claim 10, wherein a ratio of a width of the first protruding structure to a width of the baffle plate ranges from 0.4 to 0.7, wherein the width is measured along a direction from the side plate to the side wall of the photovoltaic laminate.

14. The photovoltaic module according to claim 10, wherein a cross section of the first protruding structure is in a shape of a triangle.

15. The photovoltaic module according to claim 10, wherein a plurality of limiting protrusions are arranged at intervals on the bottom plate, and each of the limiting protrusions extends along the length direction of the side plate.

16. The photovoltaic module according to claim 15, wherein a protruding height of each of the limiting protrusions is greater than or equal to 0.3 millimeters and less than or equal to 0.7 millimeters.

17. The photovoltaic module according to claim 10, wherein the photovoltaic module frame further comprises a reinforcing plate arranged opposite to the side plate and a bearing plate fixed to the first side of the side plate, wherein one end of the reinforcing plate is connected to an end of the bottom plate facing away from the side plate, and the other end of the reinforcing plate is connected to the bearing plate; and
a glue storage plate is arranged on a second side of the reinforcing plate, the second side of the reinforcing plate is a side of the reinforcing plate facing away from the side plate, a glue storage groove is provided on the glue storage plate, and the glue storage groove extends along the length direction of the side plate.

18. The photovoltaic module according to claim 17, wherein a cross section of the glue storage groove is rectangular or arc-shaped.

19. The photovoltaic module according to claim 17, wherein an end of the glue storage plate facing away from the reinforcing plate inclines toward the bearing plate to form an inclined portion, and the glue storage groove is connected to the inclined portion through a chamfer.
